(19) United States
(12) Patent Application Publication
(10) Pub. No.: US 2024/0403529 A1
(43) Pub. Date: Dec. 5, 2024

(54) ZERO DIFFUSION BREAK BETWEEN STANDARD CELLS USING THREE-DIMENSIONAL CROSS FIELD EFFECT SELF-ALIGNED TRANSISTORS

(71) Applicants: Advanced Micro Devices, Inc., Santa Clara, CA (US); ATI Technologies ULC, Markham (CA)

(72) Inventors: Richard Schultz, Fort Collins, CO (US); Omid Rowhani, Kettleby (CA)

(21) Appl. No.: 18/326,835

(22) Filed: May 31, 2023

(51) Int. Cl. G06F 30/392; G06F 30/394; H01L 27/118

(52) U.S. Cl. CPC G06F 30/392; G06F 30/394; H01L 27/11807; H01L 2027/11875; H01L 2027/11881

(57) ABSTRACT

An apparatus and method for efficiently creating layout of standard cells to improve floor planning of a chip. In various implementations, an integrated circuit uses multiple standard cells with an absence of diffusion breaks at cell boundaries. The standard cells use vertically stacked non-planer transistors. Multiple transistors are formed with an active region having a length between a source region and a drain region of a single transistor. Therefore, the active regions of these transistors are not formed across multiple gate terminals. By having active regions of these transistors formed across a single gate terminal of a single transistor, there is sufficient spacing to provide electrical isolation between two active regions of the two adjoining standard cells. This is true even when the two adjoining standard cells share a source/drain region at the cell boundaries. Accordingly, forming diffusion breaks at the edges of these standard cells can be skipped.

### BACKGROUND

### Description of the Relevant Art

As both semiconductor manufacturing processes advance and on-die geometric dimensions reduce, semiconductor chips provide more functionality and performance while consuming less space. While many advances have been made, design issues still arise with modem techniques in processing and integrated circuit design that limit potential benefits. For example, capacitive coupling, electro migration, short channel effects such as at least leakage currents, and processing yield are some issues which affect the placement of devices and the routing of signals across an entire die of a semiconductor chip. These issues have the potential to delay completion of the design and affect the time to market.

In order to shorten the design cycle for semiconductor chips, manual full-custom designs are replaced with automation where possible. In some cases, a standard cell layout is created manually. In other cases, the rules used by the place-and-route tool are adjusted to automate the cell creation. However, the automated process at times does not satisfy each of the rules directed at performance, power consumption, signal integrity, process yield, both local and external signal routing including internal cross coupled connections, pin access, and so on. Therefore, designers manually create these cells to achieve better results for the multiple characteristics or rewrite the rules for the place-and-route tool. However, many times, the layout tools and rules are setup for planar devices, rather than for the relatively recent non-planar devices.

In addition, the dimensions of the individual components of a semiconductor chip have limits in order to place all of the components on a same die or a same package. The dimensions of one or more standard cells, such as the height or the width, can be large enough that they interfere with the placement of other components. The layout tools also follow rules regarding minimum dimensions between multiple replicated standard cells, which further increase the required on-die area. In some cases, the multiple placed cells do not even fit within the same die or the same package. Consequently, the chip is rendered inoperable without significant redesign. In other cases, the components fit within the same die or package, but their placement creates unused space on the die or package results. In this case, the placement of the components is deemed inefficient, as otherwise usable space is rendered unusable due to the placement.

In view of the above, methods and systems for efficiently creating layout of standard cells to improve floor planning of a chip are desired.

### BRIEF DESCRIPTION OF THE DRAWINGS

FIG. 1 is a generalized diagram of a cross-section view of a semiconductor device layout of vertically stacked transistors.

FIG. 2 is a generalized diagram of a cross-section view and a top view of semiconductor device layouts that use vertically stacked transistors.

FIG. 3 is a generalized diagram of a cross-section view of semiconductor device layout of vertically stacked transistors and corresponding power connections.

FIG. 4 is a generalized diagram of a cross-section view of semiconductor device layout of transistors of neighboring standard cells using a diffusion break between them.

FIG. 5 is a generalized diagram of a top section view of semiconductor device layout of adjoining standard cells with no diffusion breaks between the adjoining standard cells.

FIG. 6 is a generalized diagram of a top section view of semiconductor device layout of adjoining standard cells with no diffusion breaks between the adjoining standard cells.

FIG. 7 is a generalized diagram of a top section view of semiconductor device layout of adjoining standard cells with no diffusion breaks between the adjoining standard cells.

FIG. 8 is a generalized diagram of a top section view of semiconductor device layout of adjoining standard cells with no diffusion breaks between the adjoining standard cells.

FIG. 9 is a generalized diagram of a top section view of semiconductor device layout of adjoining standard cells with no diffusion breaks between the adjoining standard cells.

FIG. 10 is a generalized diagram of a method for efficiently creating layout for adjoining standard cells absent of any diffusion breaks between the standard cells.

FIG. 11 is a generalized diagram of a method for utilizing layout that includes adjoining standard cells absent of any diffusion breaks between the standard cells.

FIG. 12 is a generalized diagram of computing system with an integrated circuit that uses adjoining standard cells absent of any diffusion breaks between the standard cells.

FIG. 13 is a generalized diagram of tables illustrating the layout area reduction of multiple types of standard cells with no diffusion break between them.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Systems and methods for efficiently creating layout of standard cells to improve floor planning of a chip are contemplated. In various implementations, an integrated circuit uses one or more standard cells that include a transistor pair of vertically stacked non-planer transistors. As used herein, a “transistor” is also referred to as a “field effect transistor” (FET), a “semiconductor device” or a “device.” In some implementations, the pair of transistors are vertically stacked gate all around (GAA) transistors such as a top vertical GAA transistor (or GAA transistor) is formed vertically on top of a bottom GAA transistor with at least an isolating oxide layer in between the two GAA transistors. It is understood that a silicon wafer, an integrated circuit, and a semiconductor package using the silicon substrate layer can be rotated and flipped. Therefore, the materials and layers being described would be rotated and flipped, and the orientations and directions would have a different meaning. Therefore, the terms “top,” “bottom,” “horizontal,” “vertical,” “left,” “right,” “above,” and “below” can change as the layout is rotated or flipped.

As used herein, an “active layer” refers to a region of a semiconductor wafer where doped silicon is formed. An “active layer” can also be referred to as an “active region” or a “diffusion region.” For planar transistors (devices), the active layer defines the regions where the silicon substrate is doped with either p-type atoms (dopants) or n-type atoms (dopants). During doping of the silicon substrate material of a semiconductor fabrication process, the impurity atoms (dopants) move by diffusion (or movement or migration based on doping gradients) at high temperatures into the silicon substrate material. For non-planar transistors (devices), the active layer defines the regions of the three-dimensional structures above the silicon substrate that contain doped silicon such as where the channels are formed. In various implementations, multiple transistors are formed with an active region having a length no greater than a distance between a source region and a drain region of a single transistor. Therefore, the active regions of these transistors are not formed across multiple gate terminals, but rather, across a single gate terminal of a single transistor. As used herein, a “terminal” of a transistor is also referred to as a “region” of a transistor. For example, a source region is also referred to as a source terminal, a drain region is also referred to as a drain terminal, and a gate region is also referred to as a gate terminal.

One or more standard cells using these transistors are formed with an absence of diffusion breaks (“zero diffusion breaks”) at one or more edges of a corresponding standard cell. For example, at least one edge of the standard cell has an absence of a diffusion break. As used herein, a “diffusion break” is a region where no doped silicon is formed. Therefore, in such a region, there is no active layer (or no active region or no diffusion region). A diffusion break is typically used to provide electrical isolation between regions. In an implementation, there are also no source/drain regions formed. In some implementations, the diffusion break is formed over an insulation layer, rather than being formed on top of a silicon substrate. The isolation layer uses a silicon nitride layer, a silicon oxide layer, such as a silicon dioxide layer, or another type of dielectric layer.

In an implementation, the region of a diffusion break includes a dummy gate structure that allows a semiconductor fabrication process to continue to form gate structures, using metal gate material, in a repeating pattern (width and pitch), which increases semiconductor die yield. However, there is no active region formed for the dummy gate structure. Therefore, should voltage levels be applied on the dummy gate structure (or dummy gate) and one or more of the regions on either side of the dummy gate, such as source/drain regions, no electrical path is provided and no current flows across the dummy gate. In contrast, an active gate structure is a gate structure formed with the metal gate material and an active region is formed for the gate structure. Therefore, should voltage levels be applied on the active gate structure (or active gate) and one or more of the regions on either side of the active gate, such as source/drain regions, an electrical path is provided and current flows across the active gate.

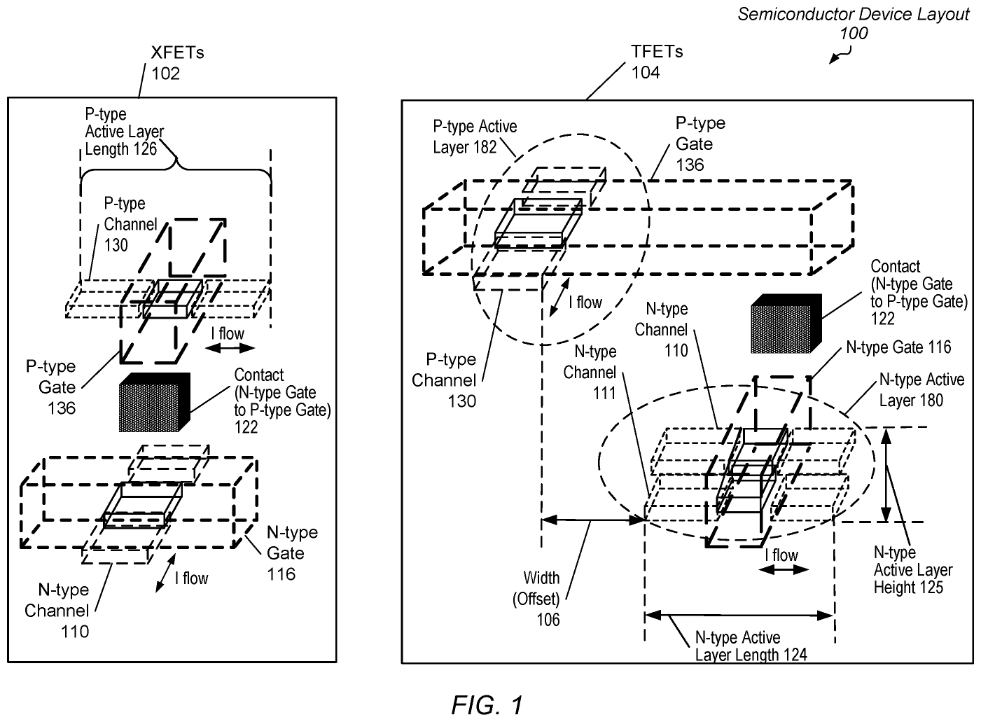

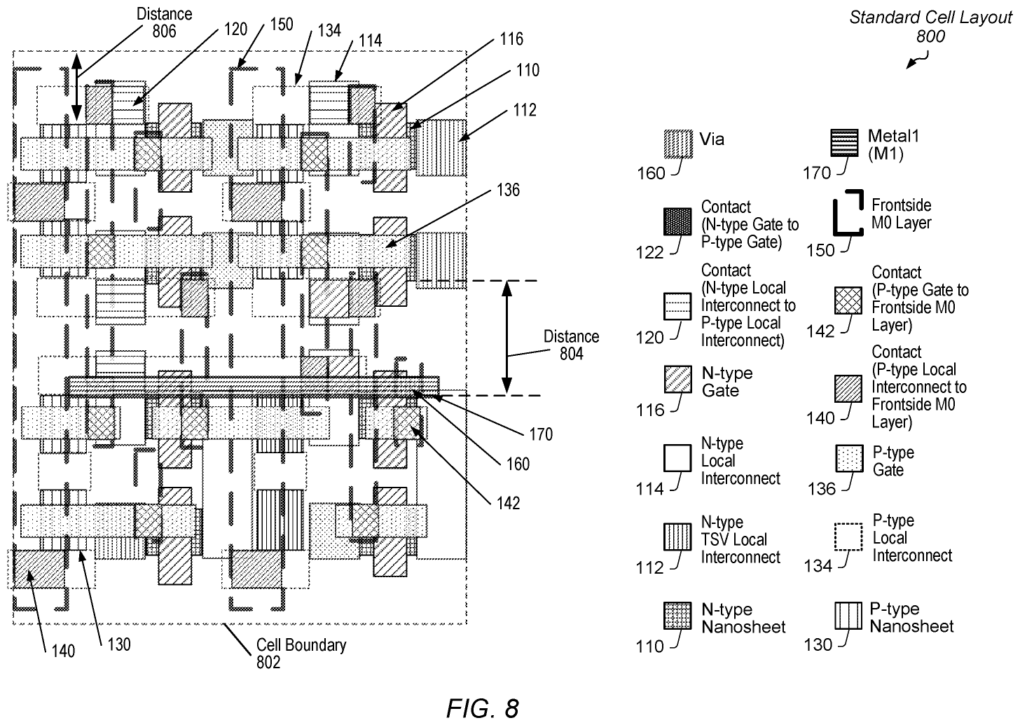

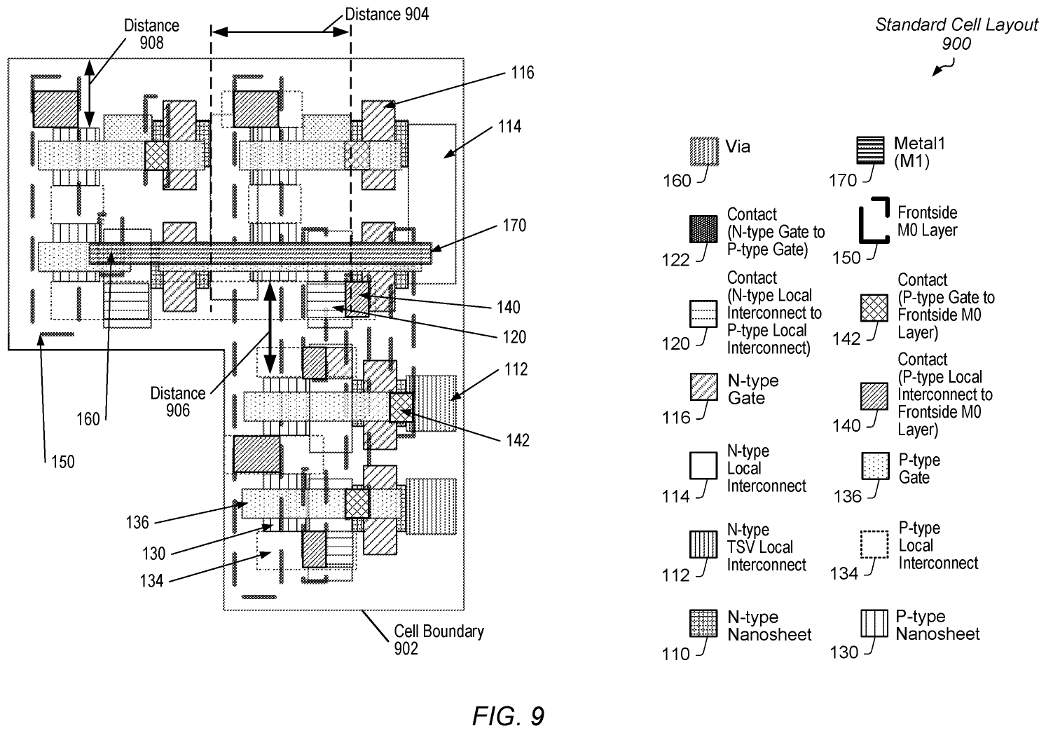

A diffusion break provides electrical isolation between silicon doped regions. An example of these regions is the active regions of two separate, but adjoining, standard cells. However, the integrated circuit includes at least two adjoining standard cells with an absence of diffusion breaks between them. By having active regions of these transistors formed across a single gate terminal of a single transistor, rather than formed across multiple gate terminals, forming diffusion breaks at the edges of these standard cells can be avoided. In other words, forming diffusion breaks at the edges of these standard cells is unnecessary. This is true even when the two adjoining standard cells share a source/drain region at the cell boundaries. There is sufficient spacing to provide electrical isolation between two active regions of the two adjoining standard cells. Therefore, each of the multiple n-type gates of the two adjoining standard cells is an active gate, and each of the multiple p-type gates of the two adjoining standard cells is an active gate. Further details of standard cells with an absence of diffusion breaks at cell boundaries are provided in the below description of FIGS. 1-12.

Turning now to FIG. 1, a generalized block diagram is shown of a cross-section view of semiconductor device layout 100 that uses vertically stacked transistors. The semiconductor materials of Cross field effect transistors (FETs) 102 are shown in the left diagram or box. Cross FETs are also referred to as “XFETs.” Therefore, the Cross FETs 102 are also referred to as XFETs 102. The gate terminals of the XFETs 102 are oriented in an orthogonal direction with respect to one another, and the gate terminals overlap one another. Therefore, these gate terminals form a cross or an X-shape from a top view as shown for the XFETs 102. The gate terminals of T-shaped FETs are oriented in an orthogonal direction with respect to one another, but the gate terminals do not overlap one another. Therefore, these gate terminals form a T-shape from a top view. The T-shaped FETs are also referred to as “TFETs.” The semiconductor materials of TFETs 104 are shown in the right diagram or box. Three-dimensional (3-D) illustrations of the p-type and n-type Cross FETs 102 and TFETs 104 are shown. Each of the XFETs 102 and the TFETs 104 include a p-type device that is vertically stacked on an n-type device. The n-type device includes at least an n-type gate 116 formed all around an n-type channel 110. Similarly, a p-type gate 136 is formed all around a p-type channel 130. Therefore, the p-type channel 130 has a doping polarity that is an opposite polarity of the n-type channel 110 of the bottom n-type device.

A pair of non-planar n-type and p-type adjacent transistors in each of the XFETs 102 and the TFETs 104 has only one transistor of the pair of transistors being adjacent to a silicon substrate. For example, the XFETs 102 include only the n-type transistor with the n-type gate 116 being adjacent to the silicon substrate (not show, but located below the n-type transistor). The p-type transistor with the p-type gate 136 is adjacent to the n-type transistor with the n-type gate 116, but the p-type transistor is not adjacent to the silicon substrate. The transistors of the TFETs 104 are shown to have the same placement relationship with respect to the silicon substrate.

Although a single n-type channel 110 and a single p-type channel 130 is shown for the Cross FETs 102, in other implementations, the semiconductor devices include another number of conducting channels (or channels). As an example, the TFETs 104 include the n-type channel 110 and the n-type channel 111. The n-type channel 110 is used to form n-type active gates, and the p-type channel 130 is used to form p-type active gates. In some implementations, the channel includes one or more conducting lateral nanowires. In other implementations, the channel includes one or more conducting nanosheets. A nanosheet is a sheet of doped silicon, rather than a wire of doped silicon. In other words, the nanosheet is a wider conductive wire than a lateral nanowire. The nanosheet can also be considered as a Fin that is rotated and placed on its side vertically above the silicon substrate such that the nanosheet does not have physical contact with the silicon substrate. Rather, metal gate is formed between the nanosheet and the silicon substrate. This visualization, though, does not describe the actual fabrication steps for forming the nanosheet.

Compared to Fin FETs, the use of gate all around (GAA) nanowires or nanosheets provides lower threshold voltages, faster switching times, less leakage currents, and further reduction of short channel effects. Examples of short channel effects other than leakage current are latchup effects, drain-induced barrier lowering (DIBL), punchthrough, performance dependency on temperature, impact ionization, and parasitic capacitance to the silicon substrate. As described earlier, an “active layer” refers to a region of a semiconductor wafer where doped silicon is formed. For planar transistors (devices), the active layer defines the regions where the silicon substrate is doped with either p-type atoms (dopants) or n-type atoms (dopants). For non-planar transistors (devices), the active layer defines the regions of the three-dimensional structures above the silicon substrate that contain doped silicon such as where the channels are formed.

In the illustrated implementations, the XFETs 102 has an n-type active layer (not labeled) that includes the single n-type channel 110. In other implementations, the n-type active layer of the n-type device includes multiple n-type channels, rather than the single n-type channel 110. The XFETs 102 has a p-type active layer (not labeled) that includes the single p-type channel 130. In other implementations, the p-type active layer of the p-type device includes multiple p-type channels, rather than the single p-type channel 130. In the illustrated implementations, the TFETs 104 has an n-type active layer 180 that includes the n-type channel 110 and the n-type channel 111. In other implementations, the n-type active layer 180 of the n-type device includes another number of n-type channels.

The TFETs 104 has a p-type active layer 182 that includes the single p-type channel 130. In other implementations, the p-type active layer 182 of the p-type device includes multiple p-type channels, rather than the single p-type channel 130. In various implementations, n-type active layer 180 and the p-type active layer 182 has a length no greater than a distance between a source region and a drain region (these source/drain regions are not shown) of a single transistor such as the n-type device and the p-type device. The source and drain regions are typically formed in a same orientation (horizontal or vertical) as corresponding gate metal of a same device. Examples of the source and drain regions are trench silicide contacts. In some implementations, the source and drain regions include Cobalt silicide (CoSi₂). In other implementations, the source and drain regions include Titanium silicide (TiSi₂) or ruthenium (Ru). These active layers 180 and 182 are not formed across multiple gate terminals. By having the active layers 180 and 182 formed across a single gate terminal of a single transistor, there is sufficient spacing to provide electrical isolation between two active regions of the two adjoining standard cells.

With one or more channels, the p-type active layer 182 of the p-type device includes a three-dimensional area with dimensions such as a length, a width, and a height. These dimensions correspond to the dimensions of the one or more p-type channels (or p-type nanosheets). For example, the p-type active layer length 126 is the same as the length of the one or more p-type channels such as p-type channel 130. Similarly, the n-type active layer length 124 is the same as the length of the one or more n-type channels such as the length of the n-type channel 110 or the same length of the n-type channel 111. The n-type active layer height 125 of the n-type active layer 180 is the same as the overall height of the one or more n-type channels, such as the overall height of the n-type channel 110 and the n-type channel 111. The p-type active layer width (not labeled) is the same as the width of the one or more p-type channels. Similarly, the n-type active layer width (not labeled) of the n-type active layer 180 is the same as the width of the n-type channel 110, which is the same as width of the n-type channel 111.

The n-type channel 110 and the n-type gate 116 are oriented in an orthogonal direction to the p-type channel 130 and the p-type gate 136. In other words, the n-type channel 110 and the n-type gate 116 are oriented in a direction that is 90 degrees from a direction of the p-type channel 130 and the p-type gate 136. Therefore, the direction of current flow of the bottom n-type device through the n-type channel 110 is orthogonal to the direction of current flow of the p-type channel 130 of the top p-type device. The directions of current flow for each of the XFETs 102 and the TFETs 104 are shown with arrows and the label “I flow.” With the orthogonal orientation between the top p-type device and the bottom n-type device, both devices have the maximum mobility for their respective carriers based on their orientation. In addition, the orthogonal orientation of the top p-type device and the bottom n-type device allow connections between the vertically stacked devices to use a single via layer.

Complementary FETs (CFETs), which are not shown, include a top GAA transistor vertically stacked on top of a bottom GAA transistor with at least an oxide layer in between for isolation. Therefore, CFETs, XFETs, and TFETs use vertically stacked GAA transistors. A pair of non-planar n-type and p-type adjacent transistors in each of the CFETs, XFETs, and TFETs has only one transistor of the pair of transistors being adjacent to a silicon substrate. Vertically stacking a top GAA transistor on top of a bottom GAA transistor further increases performance, reduces power consumption, reduces on-die area consumed by the GAA transistors. However, CFETs uses a top GAA transistor with one or more channels aligned in a same direction as the one or more channels of the bottom GAA transistor. CFETs do not rotate the top and bottom GAA transistors with respect to one another. However, as shown here, XFETs 102 and TFETs 104, have an orthogonal orientation between the one or more channels of the top GAA transistor and the one or more channels of the bottom GAA transistor.

Compared to Complementary FETs, XFETs 102 and TFETs 104 have better drive current for each of the top GAA transistor and the bottom GAA transistor, which leads to higher performance. Complementary FETs typically use at least two metal layers and three via layers to create connections between the top GAA transistor and the bottom GAA transistor. In contrast, XFETs 102 and TFETs 104 utilize a single metal layer and a single via layer for connections between the top and bottom GAA transistors.

Insulating layers are between the top p-type device and the bottom n-type device with a gate contact 122 formed between the devices in the insulating layers when the gate terminals of the pair of devices (the p-type device and the n-type device) receive a same input signal. The gate contact 122 between the vertically stacked devices is directly connected to the p-type metal gate 136 and the n-type metal gate 116 without traversing any metal layers. One advantage of the orthogonal orientation of the XFETs 102 and the TFETS 104 is the use of a single via layer, which is shown later in semiconductor layout of memory bit cells. The use of a single via layer reduces resistance and capacitance of a corresponding circuit.

As shown, the gate contact 122 of the XFETs 102 overlaps each of the n-type active layer and the p-type active layer of the two vertically stacked transistors. Since the illustrated implementation of the XFETs 102 includes a single channel for each of the p-type device and the n-type device, the active layers in the illustrated implementation include the single channels 110 and 130. The gate contact 122 overlaps each of the n-type channel 110 and the p-type channel 130. In contrast, the gate contact 122 of the TFETs 104 overlaps only one active layer of the p-type active layer 182 of the p-type device and the n-type active layer 180 of the n-type device where the p-type device and the n-type device form two vertically stacked devices. In the illustrated implementation, the gate contact 122 of the TFETs 104 overlaps only the n-type active layer 180 that includes the n-type channel 110 and n-type channel 111. Therefore, the gate contact 122 of the TFETs 104 overlaps only the n-type active layer 180. The gate contact 122 of the TFETs 104 does not overlap the p-type active layer 182.

For the TFETs 104, in various implementations, the p-type active layer 182 does not overlap the n-type active layer 180. A distance between the p-type active layer 182 and the n-type active layer 180 is shown as the width (or offset) 106. The width 106 includes at least a width of a source contact or a drain contact. In some implementations, the width 106 also includes another minimum distance between the p-type channel 130 and a source or drain contact that is determined by design rules and checks of the particular semiconductor fabrication process used to fabricate the TFETs 104. In an implementation, this minimum distance is 3 nanometers (nm) and a width of a source or drain contact is 18 nm. In such an implementation, the minimum width for the width 106 is 21 nm (3 nm+18 nm is 21 nm).

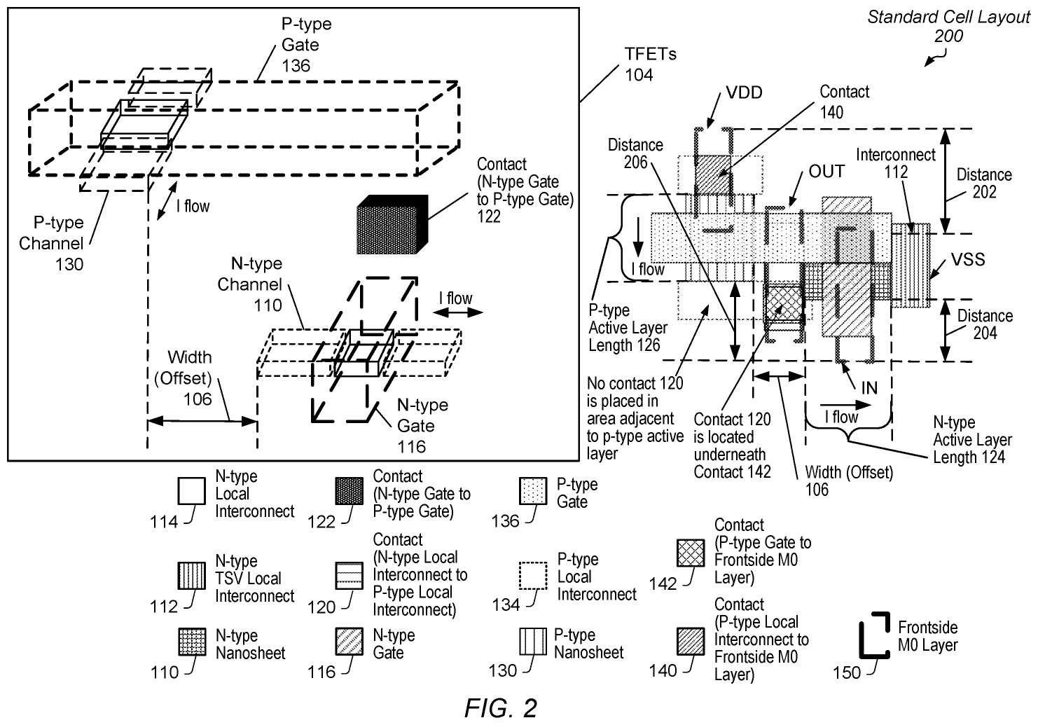

Referring to FIG. 2, a generalized block diagram of a top view of semiconductor device layout 200 is shown that uses TFETs. Contacts (or vias), semiconductor materials, and structures described earlier are numbered identically. The standard cell layout 200 (or layout 200) is a top view of standard cell layout for an inverter using TFETs 104. A three-dimensional (3-D) illustration of the p-type and n-type TFETs 104, which are shown in the box on the left, accompanies the top view of the layout 200 of the inverter shown on the right. The inverter corresponding to the layout 200 uses a p-type TFET of the TFETs 104 and an n-type TFET of the TFETs 104 in addition to interconnect materials to complete the electrical connections that provide the functionality of the inverter. For example, the nodes labeled “IN” and “OUT” store Boolean complementary values with respect to one another. For this inverter, a p-type device is being vertically stacked on an n-type device. However, in other implementations, it is possible and contemplated to have an n-type device vertically stacked on a p-type device. Each of the devices of the inverter, corresponding to the layout 200 that provides a top view of standard cell layout, uses gate all around (GAA) metal that wraps around one or more nanosheets in the gate region in a 360-degree manner. The bottom n-type device is fabricated on a first wafer. The top p-type device is fabricated on a separate second wafer, which is then oxide to oxide bonded to the first wafer. As shown, the gate contact 122 overlaps only one active layer of the n-type active layer and the p-type active layer.

The inverter, corresponding to the layout 200 that provides a top view of standard cell layout, uses a frontside power metal zero (or metal 0, M0 or Metal0) layer 150 to provide a power supply reference level indicated as “VDD.” The inverter uses an n-type through silicon via (TSV) local interconnect layer 112 to provide a ground reference level indicated as “VSS.” The contact 140 connects the frontside M0 layer 150 to the p-type local interconnect 134 to route VDD to the source region of the p-type device. The frontside M0 layer 150 is also used to route the input signal “IN” and the output signal “OUT.” For the input signal “IN,” contact 142 connects the frontside M0 layer 150 to the p-type gate 136. For the input signal “IN,” contact 122 connects the p-type gate 136 to the n-type gate 116. The drain region of the n-type device uses the n-type local interconnect 114. The drain region of the p-type device uses the p-type local interconnect 134. Contact 120 connects these two drain regions together. The contact 120 is located between the drain nodes of the p-type transistor and the n-type transistor and contacts an area of the p-type local interconnect 134 of the p-type transistor.

For the output signal “OUT,” the contact 140 overlaps the area of the contact 120 and connects the p-type local interconnect 134 to the frontside M0 layer 150. The inverter uses a backside power metal zero (or metal 0 or M0 or Metal0) layer located below the silicon substrate layer and any oxide layer (not shown), which is used for isolation. A micro through silicon via (TSV) traverses the silicon substrate layer in order to be placed between the backside power M0 rail and the source region of the n-type device. Since the inverter, corresponding to the layout 200, uses the TFETs 104, the current in the n-type device flows in an orthogonal direction with respect to the current flow in the p-type device. The orthogonal relationship of current flow is shown in the TFETs 104 and in the top view provided by the layout 200. The directions of current flow for each of the n-type devices and the p-type devices are shown with arrows and the label “I flow.”

The active layer length dimensions 124 and 126 are shown in addition to the direction of current flow (I flow) of the two devices. The width 106 between the p-type active layer and the n-type active layer includes preferably at least a width of a source or drain contact 120. In some implementations, the rules used of the place-and-route tool indicate that the width 106 should be at least the width of a source or drain contact 120. In other implementations, these rules indicate another distance threshold value. These rules of the place-and-route tool are determined by a semiconductor fabrication manufacturer and are set to increase the yield of fabricated semiconductor integrated circuits. Here, the inverter uses the contact 120 as a drain contact. The active layer length dimensions 124 and 126 do not traverse across the inverter, but rather, have lengths smaller than dimensions of the standard cell of the inverter. The p-type active layer length 126 is no longer than a distance between a source region and a drain region of the single p-type transistor.

Similar to the p-type active layer length 126, the n-type active layer length 124 is preferably no longer than a distance between a source region and a drain region of the single n-type transistor. In an implementation, the n-type active layer length 124 (and the p-type active layer length 126) is limited by a threshold distance based on the rules used by the place-and-route tool, and these rules are provided by a semiconductor fabrication manufacturer. Therefore, distances to active layers of any adjoining standard cells can be large enough to provide electrical isolation between active layers with an absence of diffusion breaks between the adjoining standard cells. The distance 202 is a distance from the n-type active layer implemented by the n-type nanosheet 110 to the top of the inverter standard cell. The distance 204 is a distance from the n-type active layer to the bottom of the inverter standard cell. The distances 202 and 204 will have additional distances within an adjoining standard cell before reaching another active layer. These combined distances across the adjoining standard cells that use the distances 202 and 204 are sufficiently long enough to provide electrical isolation between active layers with an absence of diffusion breaks between the adjoining standard cells. The distance 206 is a distance from the p-type active layer implemented by the p-type nanosheet 130 to the bottom of the inverter standard cell. The distance 206 will have an additional distance within an adjoining standard cell before reaching another active layer. These combined distances across the adjoining standard cells that use the distance 206 are sufficiently long enough to provide electrical isolation between active layers with an absence of diffusion breaks between the adjoining standard cells. A similar distance exists between the p-type active layer to the top of the inverter standard cell.

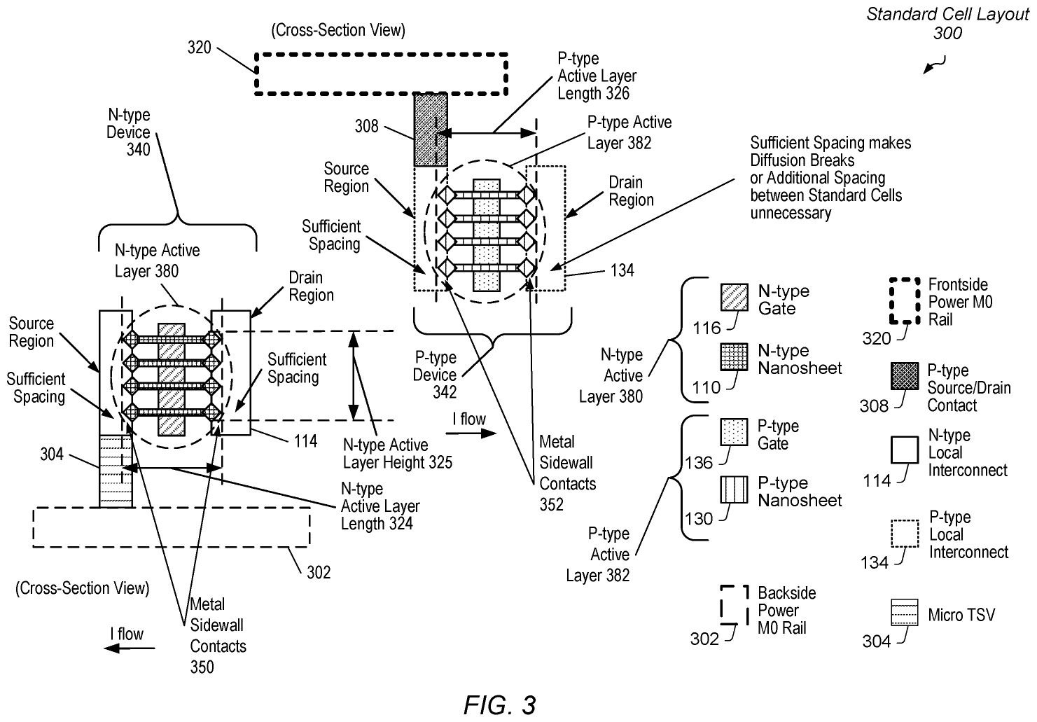

Referring to FIG. 3, a generalized block diagram is shown of a cross-section view of a standard cell layout 300 that utilizes power connections routed in a frontside metal layer and a backside metal layer. Contacts (or vias), semiconductor materials, and structures described earlier are numbered identically. The standard cell layout 300 is for any of a variety of types of Boolean gates and complex gates that include transistors arranged in a particular manner for providing data processing functionality or providing data storage. The standard cell layout 300 (or layout 300) uses TFETs. In other implementations, the standard cell layout 300 uses XFETs. The TFETs include the n-type device 340 and the p-type device 342. Although the cross-section view shows each of the two transistors (devices) 340 and 342 with metal gates oriented in a same direction, the actual placement of these transistors in semiconductor layout includes orthogonal placement with respect to one another. Power signals are routed using both frontside and backside metal layers.

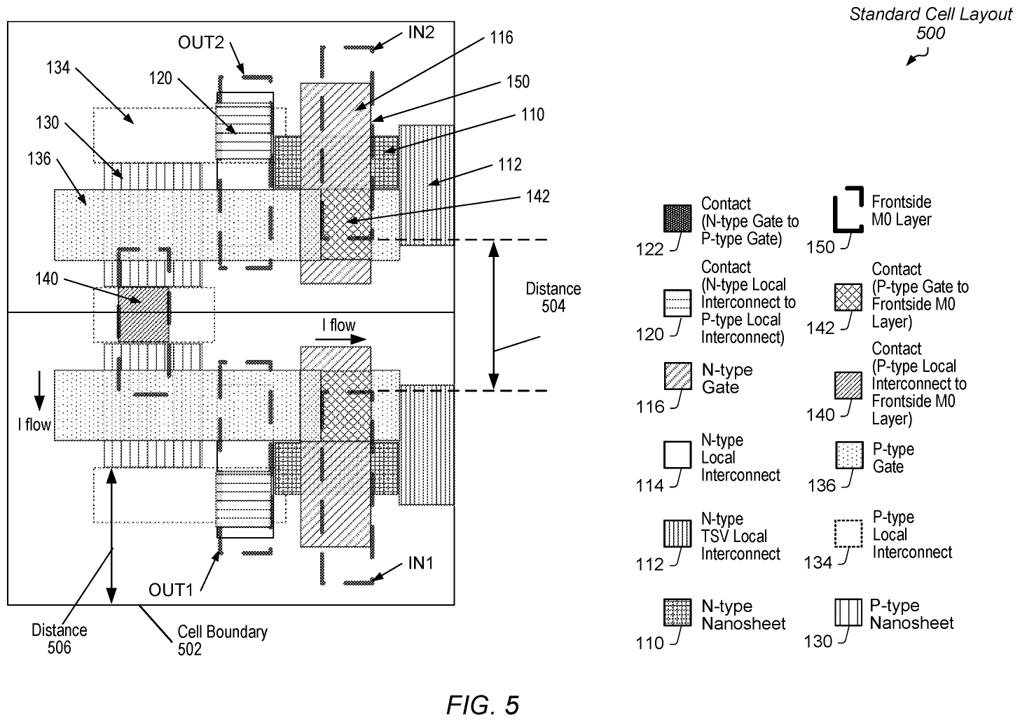

Here, a first transistor of the TFETs, such as the n-type device 340, has an n-type active layer 380 that provides current flow oriented in a first direction orthogonal to a second direction of current flow in the p-type active layer 382. In the layout 300, the directions of current flow for each of the p-type device 342 and the n-type device 340 are shown with arrows and the label “I flow.” These directions of current flow in the layout 300 are not shown as being orthogonal to one another as shown, since cross-section views are provided, rather than top views, of the p-type device 342 and the n-type device 340. The currents flow through the p-type active layer 382 and the n-type active layer 380, which are placed with an orthogonal orientation with respect to one another as shown earlier in the layouts 100 and 200 (of FIGS. 1-2). In an implementation, the n-type active layer 380 includes one or multiple n-type nanosheets. In the key or legend, the label “n-type nanosheet 110” is used. However, it is understood that an n-type active layer, such as the n-type active layer 380 (and n-type active layer 180 of FIG. 1) can include multiple n-type nanosheets as shown in the cross-section view provided in layout 300. The upcoming layouts 500-900 (of FIGS. 5-9) provide a top view, rather than a cross-section view, and accordingly, only a single n-type nanosheet is shown. However, it is understood that one or more additional n-type nanosheets are formed underneath the topmost n-type nanosheet as shown in layout 300 and layout 100 (of FIG. 1). The same is true for the p-type nanosheet 130.

In various implementations, each of the n-type nanosheets 110 of the n-type active layer 380 consists of a silicon semiconducting epitaxial growth layer doped with n-type atoms. Similarly, each of the p-type nanosheets 130 consists of a silicon semiconducting epitaxial growth layer doped with p-type atoms. Each of the n-type nanosheets 110 and the p-type nanosheets 130 ends within the edges of their respective drain region and source region. The drain region and source region of the n-type device 340 uses the n-type local interconnect 114 shown earlier. The drain region and source region of the p-type device 342 uses the p-type local interconnect 134 shown earlier.

In contrast to Complementary FETs, the n-type nanosheets 110 do not traverse the entirety of the drain region and the source region. Rather, the n-type nanosheets 110 utilize metal sidewall contacts 350 at the ends of the n-type nanosheets 110 within the source region and the drain region, which allows more nanosheets to be created in the n-type active layer. The p-type nanosheets 130 of the p-type active layer 382 are formed in a similar manner and also utilize metal sidewall contacts 352 at the ends of the p-type nanosheets 130 within the respective source region and drain region.

As described earlier, the n-type active layer 380 refers to a region of a semiconductor wafer where doped silicon is formed. The n-type active layer 380 of the n-type device 340 is a three-dimensional area that includes a length 324 equal to the distance between the metal sidewall contacts 350 at the ends of the nanosheets within the source region and the drain region. Similar to the n-type active layer height 125 of the n-type active layer 180 (of FIG. 1), the n-type active layer 380 has an n-type active layer height 325 equal to the distance from the bottom of the bottom n-type nanosheet 110 to the top of the top n-type nanosheet 110. Additionally, this n-type active layer 380 has a width equal to the distance that the n-type nanosheets 110 traverse along a direction going into the page (or out of the page). The p-type active layer 382 of the p-type device 342 has dimensions defined in a similar manner. For example, the p-type active layer 382 of the p-type device 342 is a three-dimensional area that includes a length 326 equal to the distance between the metal sidewall contacts 352 at the ends of the nanosheets within the source region and the drain region.

By having the active layers 380 and 382 formed across a single gate terminal of a single transistor and having the active layer lengths 324 and 326, there is sufficient spacing to provide electrical isolation between two active regions of two adjoining standard cells. These distances between active layers across two adjoining standard cells is shown in the standard cell layout 500-900 (of FIGS. 5-9). The n-type device 340 is connected to a first voltage level reference provided by a backside metal layer. This backside power metal zero (or metal 0 or M0 or Metal0) layer 302 is located below the silicon substrate layer and any oxide layer (not shown), which is used for isolation. A micro through silicon via (TSV) 304 traverses the silicon substrate layer in order to be placed between the backside power M0 layer 302 and the source region of the n-type device 340.

The TFETs also use a second transistor, such as the p-type device 342, having a second channel oriented in a second direction orthogonal to the first direction and connected to a second voltage level reference provided by a frontside metal layer. This frontside power metal zero (or metal 0 or M0 or Metal0) layer 320 is located above the silicon substrate layer and any oxide layer (not shown), which is used for isolation. The drain region and source region of the p-type device 342 uses the p-type local interconnect 134 shown earlier. The p-type source/drain contact 308 connects the source region (p-type local interconnect 134) to the M0 layer 320. In other implementations, the n-type transistor 340 and the p-type transistor 342 are switched along with the types of voltage reference levels connected to the backside power M0 layer 302 and the frontside power M0 layer 320.

The “micro TSV” 304 is a through silicon via traversing through the silicon substrate layer from the backside power M0 layer 302 to the source region using the n-type local interconnect 114, and ends with physical contact at each of the backside power M0 layer 302 to the source region. The distance between the backside power M0 layer 302 to the n-type local interconnect 114 used as the source region defines the height or length of the micro TSV 304, which traverses only the silicon substrate layer and any oxide layer above the backside power M0 layer 302. The micro TSV 304 does not physically extend into multiple insulation layers of a semiconductor die used for routing multiple frontside metal layers. Similarly, the micro TSV 304 does not physically extend into multiple insulation layers of the semiconductor die used for routing multiple backside metal layers.

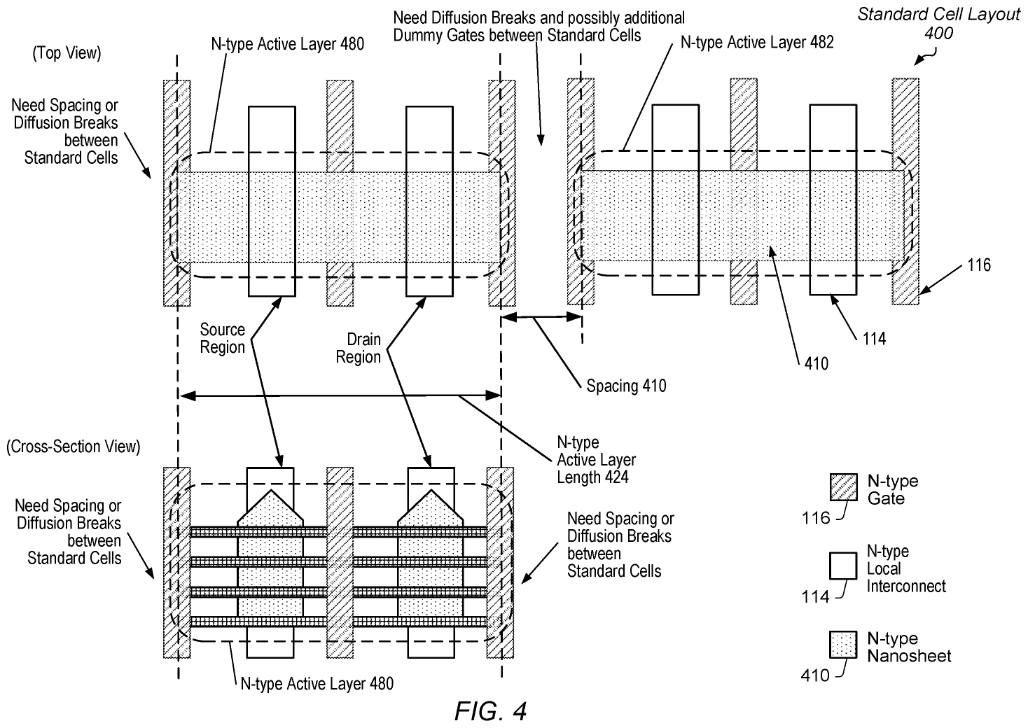

Turning now to FIG. 4, a generalized block diagram is shown of a standard cell layout 400 of adjoining standard cells using a diffusion break between them. Contacts (or vias), semiconductor materials, and structures described earlier are numbered identically. A top view of an n-type device in a standard cell using the n-type active layer 480 is shown in the top left corner of the standard cell layout 400 (or layout 400). The n-type device is used in a standard cell that uses CFETs. The adjacent p-type device is not shown. Unlike standard cells that use XFETs or TFETs, this standard cell utilizes the n-type active layer 480 with an n-type active layer length 424 (or length 424) that spans across multiple gate terminals. A cross-section view of this standard cell is shown below the top view.

In the layout 400, it is illustrated that the n-type nanosheets 410 of the n-type active layer 480 are formed across three gate terminals, rather than across a single gate terminal of a single transistor. Therefore, measuring length as a number of gate terminals, the length 424 is greater than the length 124. The source region and the drain region include the n-type nanosheet 410 across the entire lengths of these regions. The n-type local interconnect 114 is formed above and below the n-type nanosheet 410. Unlike the n-type active layers 180 and 380, the n-type active layer 480 does not end at a source region and a drain region using metal sidewall contacts 350 at the ends of the n-type nanosheets 410 within the source region and the drain region. Rather, the n-type active layer 480 ends at gate terminals (n-type gates 116).

A top view of an n-type device in a neighboring standard cell using the n-type active layer 482 is shown in the top right corner of the standard cell layout 400 (or layout 400). Similar to the n-type active layer 480, the n-type active layer 482 does not end at a source region and a drain region using metal sidewall contacts 350 at the ends of the n-type nanosheets 410 within the source region and the drain region. Rather, the n-type active layer 482 ends at gate terminals (n-type gates 116). To place the neighboring standard cells in a floorplan of a semiconductor chip, the spacing 410 between the standard cells is required to provide electrical isolation between the n-type active layer 480 and the n-type active layer 482. The two standard cells are unable to be placed on the semiconductor die (or die) with no diffusion breaks between them.

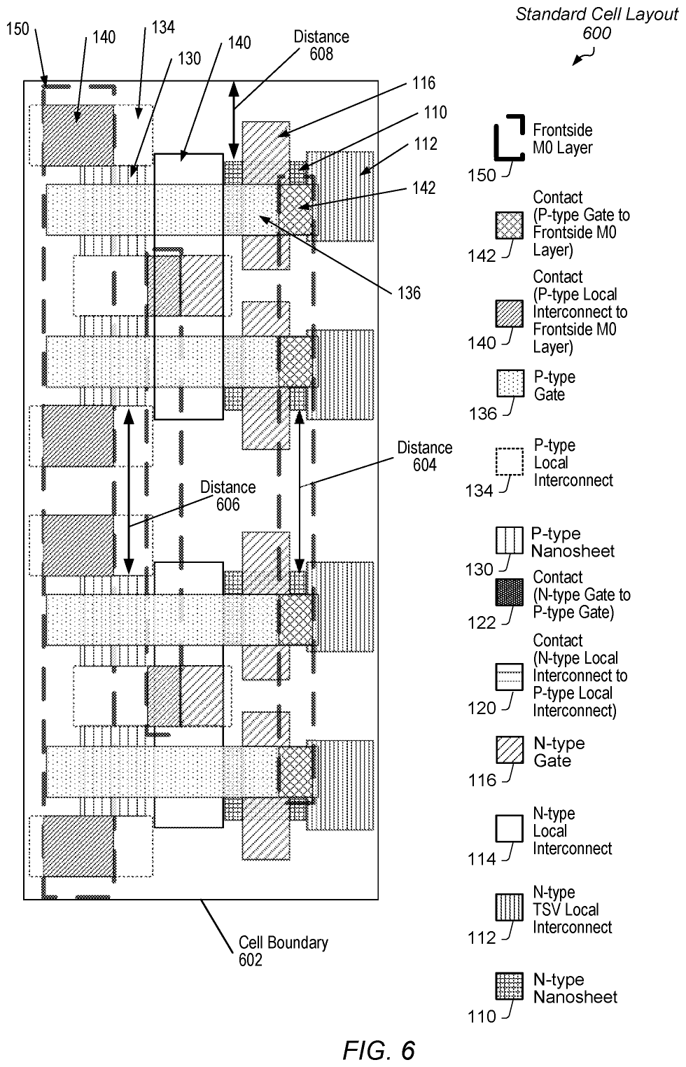

Referring to FIG. 5 and FIG. 6, generalized block diagrams are shown of a top view of semiconductor device layout 500 and 600 of adjoining standard cells with no diffusion breaks between the adjoining standard cells. Contacts (or vias), semiconductor materials, and structures described earlier are numbered identically. The standard cell layout 500 (or layout 500) is for an inverter using TFETs within the standard cell boundary 502. The layout 500 can be used for two separate inverters, or a single inverter with double the drive strength when the separate input signals are electrically shorted to one another and the separate output signals are electrically shorted to one another.

The distance 504 is a distance between the two n-type active layers of the two inverters using the n-type nanosheets 110. The distance 504 is large enough to provide electrical isolation between the two n-type active layers with an absence of diffusion breaks between the adjoining standard cells (adjoining inverters). Similarly, the distance 506 is a distance between the two p-type active layers of the two inverters using the p-type nanosheets 130. Whether another adjoining standard cell of one or two inverters is placed above or below the layout 500, the distance 506 is large enough to provide electrical isolation between two p-type active layers with an absence of diffusion breaks between the adjoining standard cells.

Although the standard cell layouts 500-900 (of FIGS. 5-9) use TFETs, in other implementations, the standard cell layouts 500-900 use XFETs. In implementations of the standard cell layouts 500-900 using TFETs or XFETs, the n-type and p-type active layers have distances between them that provide electrical isolation between two active layers with an absence of diffusion breaks between adjoining standard cells. These distances between two n-type active layers and between two p-type active layers of the standard cell layouts 500-900 using TFETs or XFETs result from each of these active layers being formed across a single gate terminal of a single transistor. In other words, in implementations of the standard cell layouts 600-1000 using TFETs or XFETs, each of the multiple p-type gates 136 and each of the multiple n-type gates 116 is an active gate. Therefore, each metal gate (p-type gate 136 or n-type gate 116) is an active gate in the standard cell layouts 600-1000. No dummy gate structures are used in implementations of the standard cell layouts 500-900 using TFETs or XFETs. This is true even when the two adjoining standard cells share a source/drain region at the cell boundaries. It is noted that although the standard cell layouts 500-900 illustrate the functionality of particular types of Boolean gates and complex gates, in other implementations, a variety of other types of Boolean gates and complex gates that include transistors arranged in a particular manner for providing data processing functionality or providing data storage also use the techniques described in the below description.

The standard cell layout 600 (or layout 600) is for an inverter using TFETs within the standard cell boundary 602 that includes transistors for 4 inverters. The layout 600 can be used for two separate inverters, or a single inverter with four times the drive strength when the separate input signals are electrically shorted to one another and the separate output signals are electrically shorted to one another. Each of the distances 604 and 606 between active layers within the cell boundary 602 is sufficiently large enough to provide electrical isolation between two active layers with an absence of diffusion breaks between the adjoining standard cells. In addition, each of the n-type and p-type active layers at the top and bottom of the cell boundary 602 have an approximate distance 608 to the cell boundary 602. This distance 608 would be doubled when another standard cell using the layout 600 is instantiated above and/or below the cell boundary 602. This total distance provide electrical isolation between two active layers with an absence of diffusion breaks between the adjoining standard cells.

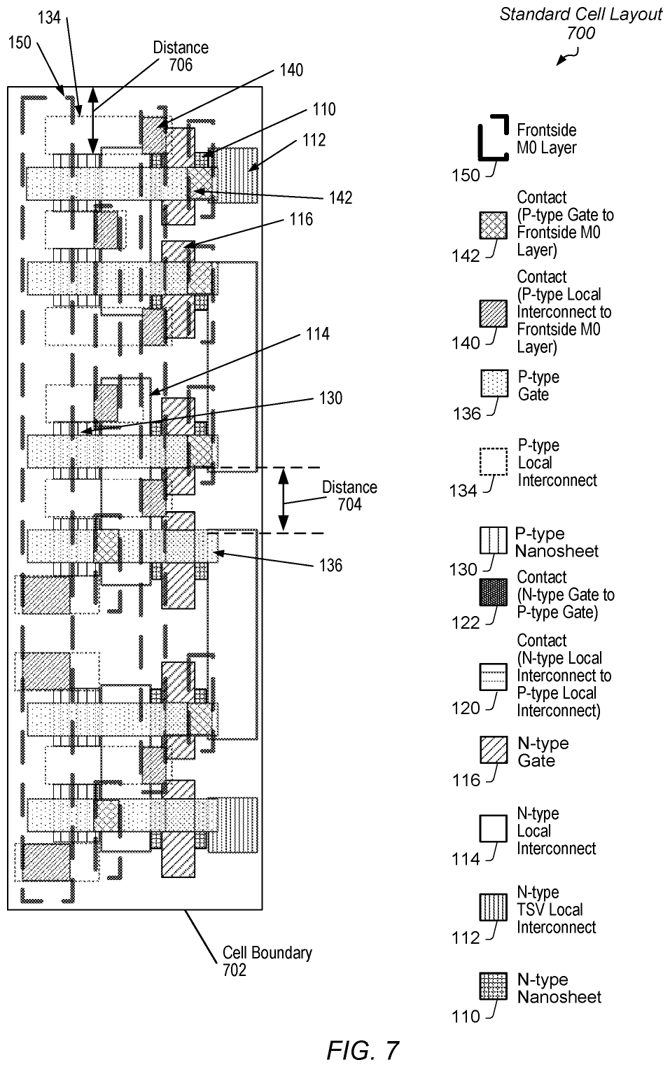

Turning now to FIGS. 7-9, generalized block diagrams are shown of a top view of a standard cell layouts 700-900 (or layouts 700-900). Contacts (or vias), materials and structures described earlier are numbered identically. One or more semiconductor fabrication elements are not included in the layouts 700-900 in order to avoid obscuring the view of the n-type and p-type active layers. The layout 700 is for a Boolean complex gate within the cell boundary 702 that provides the functionality of a 3-input AND-OR-Invert (AOI) Boolean complex gate. The layout 700 also uses adjoining (instantiated and sometimes mirrored) standard cells to provide its functionality. The layout 700 also uses the via 160 to connect the frontside M0 layer 150 to the frontside metal one (or metal 1 or M1 or Metal1) layer 170. The adjoining standard cells are placed vertically above a previous standard cell. No diffusion breaks are included between the adjoining standard cells, since the distances between the active layers is already sufficiently large enough to electrically isolate the active layers of the adjoining standard cells.

The distance 704 between n-type active layers within the cell boundary 702 is sufficiently large enough to provide electrical isolation between two active layers with an absence of diffusion breaks between adjoining standard cells. Therefore, the two adjoining standard cells can share a source/drain region between them using the p-type local interconnect 134 absent of any diffusion breaks between the adjoining standard cells. In addition, each of the n-type and p-type active layers at the top and bottom of the cell boundary 702 have an approximate distance 706 to the cell boundary 702. This distance 706 would be doubled when another standard cell using the layout 700 is instantiated above and/or below the cell boundary 702. This total distance provide electrical isolation between two active layers with an absence of diffusion breaks between the adjoining standard cells. Similar to metal gates of the layouts 500-600 and 800-900, each of the metal gates of layout 700 is an active gate within two adjoining standard cells.

The layout 800 is for a sequential data storage element, which is also referred to as a latch, within the cell boundary 802. The layout 800 uses adjoining standard cells (instantiated and sometimes mirrored) to provide its functionality. The adjoining standard cells are placed both horizontally and vertically with reference a previous standard cell. No diffusion breaks are included between the adjoining standard cells. The distance 804 between n-type active layers within the cell boundary 802 illustrates an n-type active layer does not extend across the entire standard cell, and each of the n-type active layers traverses across a single gate terminal as also shown in the layouts 500-900 (of FIGS. 5-9). In addition, each of the n-type and p-type active layers at the top and bottom of the cell boundary 802 have an approximate distance 806 to the cell boundary 802. This distance 806 would be doubled when another standard cell using the layout 800 is instantiated above and/or below the cell boundary 802. This total distance provide electrical isolation between two active layers with an absence of diffusion breaks between the adjoining standard cells.

The layout 900 is for a 2-input AOI Boolean complex gate within the cell boundary 902. The layout 900 uses adjoining standard cells (instantiated and sometimes mirrored) to provide its functionality. The adjoining standard cells are placed both horizontally and vertically with reference a previous standard cell. No diffusion breaks are included between the adjoining standard cells. The layout 900 includes an L-shape that provides available on-die area for another non-instantiated standard cell. The distance 904 between n-type active layers within the cell boundary 902 is sufficiently large enough to provide electrical isolation between two active layers with an absence of diffusion breaks between adjoining standard cells. Similarly, the distance 906 between p-type active layers within the cell boundary 902 is sufficiently large enough to provide electrical isolation between two active layers with an absence of diffusion breaks between adjoining standard cells. In addition, each of the n-type and p-type active layers at the top and bottom of the cell boundary 902 have an approximate distance 908 to the cell boundary 902. This distance 908 would be doubled when another standard cell using the layout 900 is instantiated above and/or below the cell boundary 902. This total distance provide electrical isolation between two active layers with an absence of diffusion breaks between the adjoining standard cells.

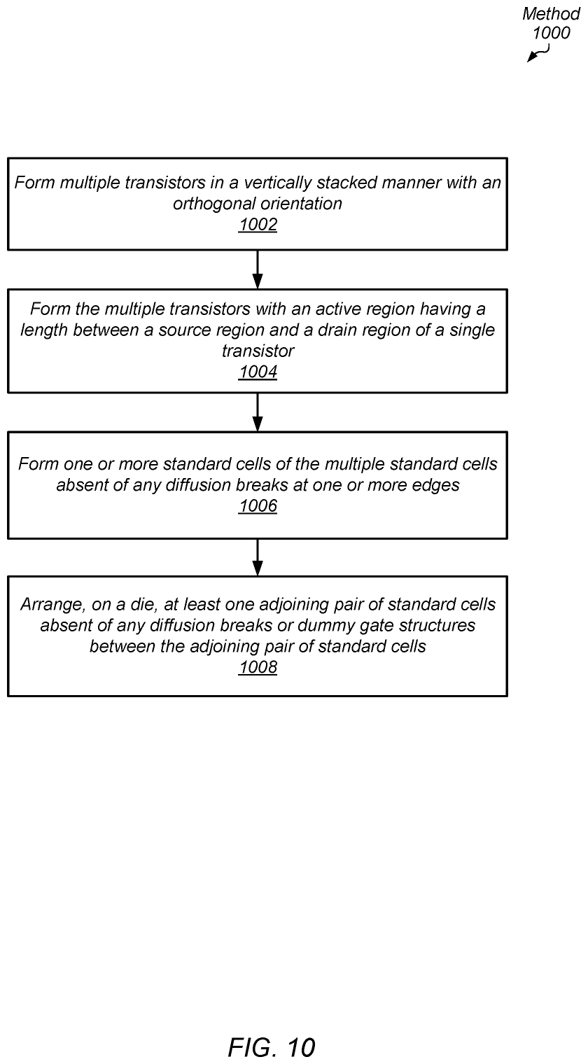

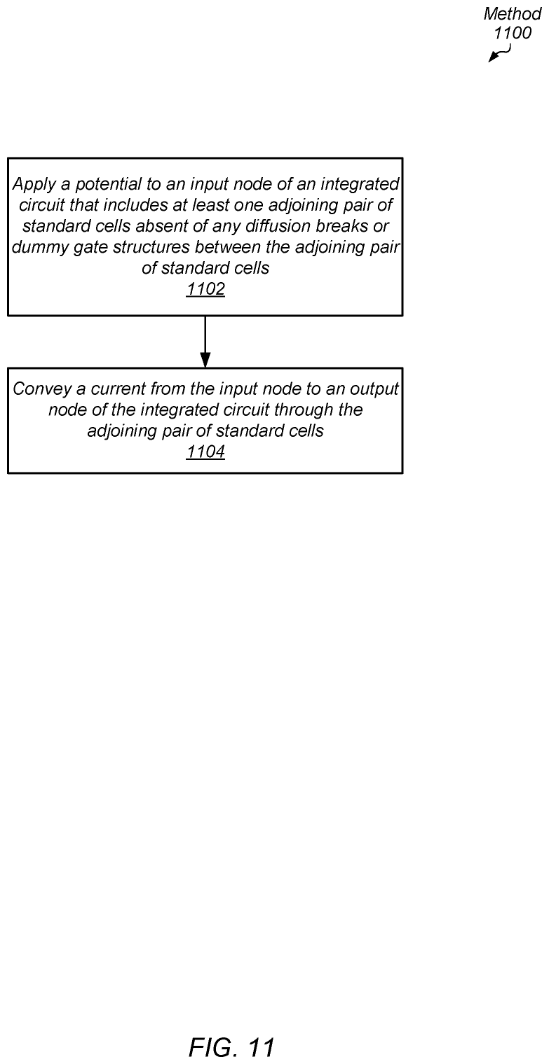

Referring now to FIG. 10, a generalized block diagram is shown of a method 1000 for efficiently creating layout for adjoining standard cells absent of any diffusion breaks between the standard cells. For purposes of discussion, the steps in this implementation (as well as for method 1100 of FIG. 11) are shown in sequential order. However, in other implementations some steps occur in a different order than shown, some steps are performed concurrently, some steps are combined with other steps, and some steps are absent.

A semiconductor fabrication processor (or process) forms multiple transistors in a vertically stacked manner with an orthogonal orientation (block 1002). A pair of non-planar n-type and p-type adjacent transistors has only one transistor of the pair of transistors being adjacent to a silicon substrate. In various implementations, the process forms XFETs or TFETs. The process forms the multiple transistors with an active region having a length between a source region and a drain region of a single transistor (block 1004). The process forms one or more standard cells of the multiple standard cells absent of any diffusion breaks at one or more edges (block 1006). The process arranges, on a die, at least one adjoining pair of standard cells absent of any diffusion breaks, such as dummy gate structures, between the adjoining pair of standard cells (block 1008).

Referring now to FIG. 11, a generalized block diagram is shown of a method 1100 for utilizing layout that includes adjoining standard cells absent of any diffusion breaks between the standard cells. A potential is applied to an input node of an integrated circuit that includes at least one adjoining pair of standard cells absent of any diffusion breaks or dummy gate structures between the adjoining pair of standard cells (block 1102). Similar to the standard cell layouts 200-300 and 500-900 (of FIGS. 2-3 and 5-9), in various implementations, the integrated circuit uses XFETs and/or TFETs to provide a variety of types of functionalities. Therefore, one or more active layers of the standard cells of the integrated circuit are formed across a single gate terminal of a single transistor, which provides electrical isolation between two active layers with an absence of diffusion breaks between adjoining standard cells. The integrated circuit conveys a current from the input node to an output node through the adjoining pair of standard cells (1104).

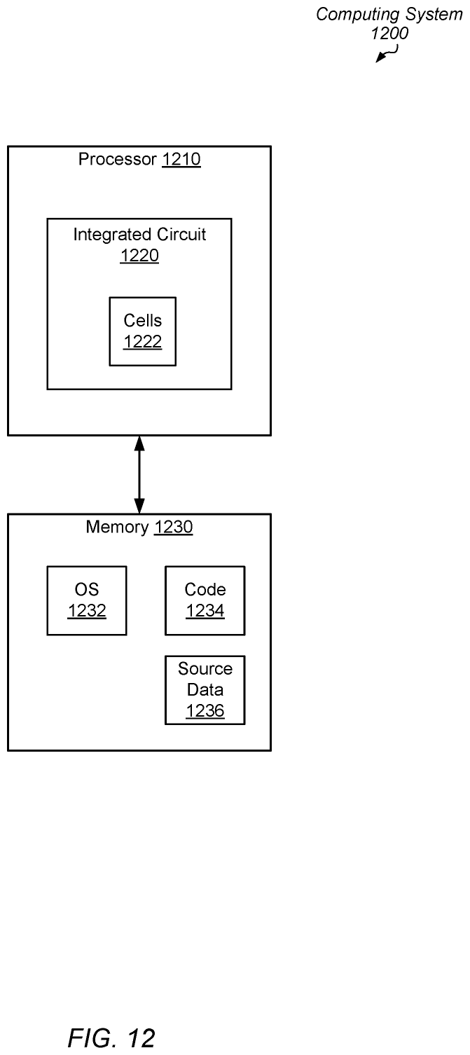

Referring to FIG. 12, a generalized block diagram is shown of a computing system 1200 is shown. The computing system 1200 includes the processor 1210 and the memory 1230. Interfaces, such as a memory controller, a bus or a communication fabric, one or more phased locked loops (PLLs) and other clock generation circuitry, power management circuitry, and so forth, are not shown for ease of illustration. It is understood that in other implementations, the computing system 1200 includes one or more of other processors of a same type or a different type than processor 1210, one or more peripheral devices, a network interface, one or more other memory devices, and so forth. In some implementations, the functionality of the computing system 1200 is incorporated on a system on chip (SoC). In other implementations, the functionality of the computing system 1200 is incorporated on a peripheral card inserted in a motherboard. The computing system 1200 is used in any of a variety of computing devices such as a desktop computer, a tablet computer, a laptop, a smartphone, a smartwatch, a gaming console, a personal assistant device, and so forth.

The processor 1210 includes hardware such as circuitry. For example, the processor 1210 includes a computing core or other circuit that uses at least one integrated circuit 1220. The integrated circuit 1220 utilizes standard cells 1222 (or cells 1222). Similar to the standard cell layouts 200-300 and 500-900 (of FIGS. 2-3 and 5-9), the cells 1222 use XFETs and/or TFETs to provide a variety of types of functionalities. Therefore, one or more active layers of the cells 1222 are formed across a single gate terminal of a single transistor, which provides electrical isolation between two active layers with an absence of diffusion breaks between adjoining standard cells. The computing core is configured to execute instructions, including instructions retrieved from memory 1230. The cells 1222 include at least one pair of adjoining standard cells with no diffusion breaks between the standard cells. In some implementations, these bit cells 1222 use the circuitry of the standard cell layouts 200-300 and 500-900 (of FIGS. 2-3 and 5-9). In various implementations, the processor 1210 includes circuitry of one or more processor cores capable of general-purpose data processing, and an associated cache memory subsystem. In such an implementation, the processor 1210 is a central processing unit (CPU). In another implementation, the processing cores include the circuitry of a highly parallel data microarchitecture with multiple parallel execution lanes and an associated data storage buffer. In such an implementation, the processor 1210 is a graphics processing unit (GPU), a digital signal processor (DSP), or other.

In some implementations, the memory 1230 includes one or more of a hard disk drive, a solid-state disk, other types of flash memory, a portable solid-state drive, a tape drive and so on. The memory 1230 stores an operating system (OS) 1232, one or more applications represented by code 1234, and at least source data 1236. Memory 1230 is also capable of storing intermediate result data and final result data generated by the processor 1210 when executing a particular application of code 1234. Although a single operating system 1232 and a single instance of code 1234 and source data 1236 are shown, in other implementations, another number of these software components are stored in memory 1230. The operating system 1232 includes instructions for initiating the boot up of the processor 1210, assigning tasks to hardware circuitry (such as the processor 1210 that includes the integrated circuit 1220), managing resources of the computing system 1200 and hosting one or more virtual environments.

Each of the processor 1210 and the memory 1230 includes an interface circuitry for communicating with one another as well as any other hardware components included in the computing system 1200. The interface circuitry includes queues for servicing memory requests and memory responses, and control circuitry for communicating with one another based on particular communication protocols. The communication protocols determine a variety of parameters such as supply voltage levels, power-performance states that determine an operating supply voltage and an operating clock frequency, a data rate, one or more burst modes, and so on.

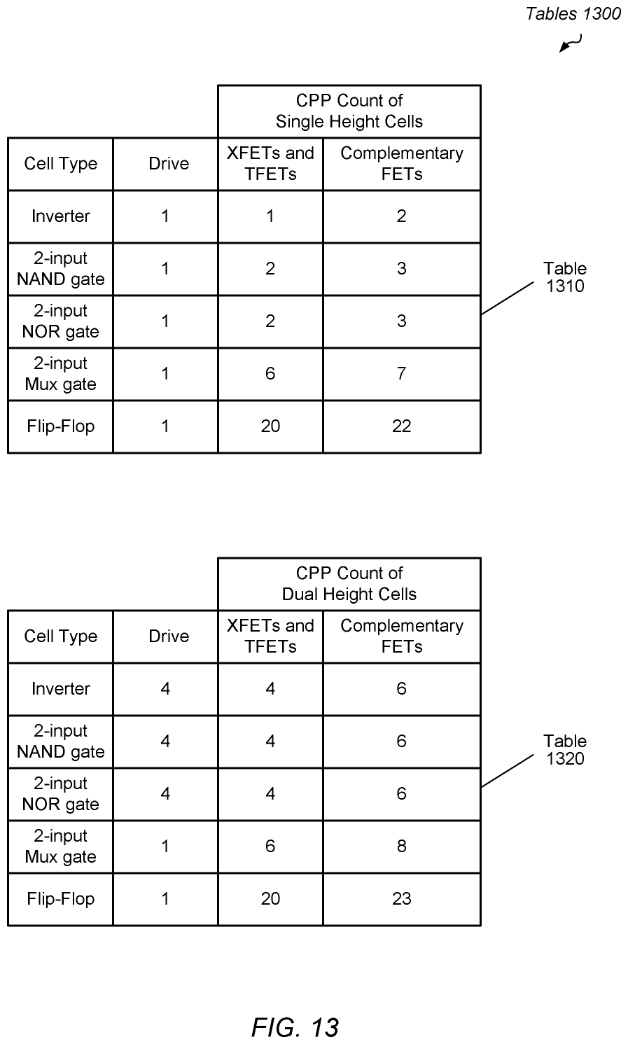

Referring to FIG. 13, a generalized block diagram of tables 1300 illustrating the layout area reduction of multiple types of standard cells with no diffusion break between them. The tables 1300 includes the table 1310 and the table 1320. The table 1310 illustrates the layout area reduction of multiple types of standard cells using a single height with no diffusion break between them. By using a single height, these cells do not include one or more instantiated copies of a cell placed above or below another cell. Each of the top half or the bottom half of the layout 500 (of FIG. 5) illustrates an inverter cell with a single height.

Although particular Boolean complex gates and a flip-flop circuit are listed in the table 1310, other types of standard cells also provide a layout area reduction for adjoining standard cells with no diffusion break between them when these standard cells utilize XFETs or TFETs such as the transistors 102 and 104 (of FIG. 1). Although particular Boolean complex gates and a flip-flop circuit are listed in the table 1310, other types of standard cells also provide a layout area reduction for adjoining standard cells with no diffusion break between them when these standard cells utilize XFETs or TFETs such as the transistors 102 and 104 (of FIG. 1).

The table 1310 (and table 1320) provides the CPP count for the layouts of different types of standard cells being generated with different types of transistors. The layouts 500-900 (of FIGS. 5-9) are characterized by a number of contacted gate pitches (CPP). The acronym CPP is used, since metal gates can be formed using polysilicon, so there would be a number of contacted polysilicon (poly) pitches, or CPP, in these layouts. However, metal gates can now also be formed from a variety of other materials. Titanium nitride (TiN) is one example of material used to form metal gates in the layouts 500-900. Although other materials can be used to form the metal gates of the layouts 500-900, the acronym CPP is still used to indicate the number of contacted gate pitches. The table 1320 illustrates the layout area reduction of multiple types of standard cells using a double height with no diffusion break between them. By using a double height, these cells include one or more instantiated copies of a cell placed above or below another cell. The layouts 600, 800 and 900 illustrates standard cells with a double height. Although not shown in the tables 1310 and 1320, the layout 700 illustrates a standard cell with a triple height.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware based type emulator from such vendors as Cadence®, EVE®, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit comprising:
a plurality of standard cells with one or more of the standard cells comprising non-planar transistors;
wherein each of a plurality of metal gates, within at least one adjoining pair of standard cells of the plurality of standard cells, is an active gate.

2. The integrated circuit as recited in claim 1, wherein standard cells of the at least one adjoining pair of standard cells have one or more active regions with a length equal to a distance between a source region and a drain region of a single transistor.

3. The integrated circuit as recited in claim 2, wherein the standard cells of the at least one adjoining pair of standard cells comprise a source region or a drain region at an edge of one of the standard cells.

4. The integrated circuit as recited in claim 3, wherein the standard cells of the at least one adjoining pair of standard cells share the source region or the drain region at the edge.

5. The integrated circuit as recited in claim 2, wherein the plurality of standard cells comprises a given group of instantiated standard cells that form an L-shape that provides available on-die area for another non-instantiated standard cell.

6. The integrated circuit as recited in claim 2, wherein the non-planar transistors comprise pairs of transistors with channels of opposite doping polarities with only one transistor of a corresponding pair of transistors being adjacent to a silicon substrate.

7. The integrated circuit as recited in claim 6, wherein responsive to a potential being applied to an input node of the integrated circuit, one or more of the standard cells convey a current from the input node to an output node of the integrated circuit.

8. A method comprising:
forming a plurality of standard cells with one or more of the standard cells comprising non-planar transistors by:
forming, in an integrated circuit of at least one of the one or more of the standard cells, a first transistor with a first channel oriented in a first direction;
forming, in the integrated circuit, an oxide layer adjacent to the first transistor;
forming, in the integrated circuit, a second transistor adjacent to the oxide layer, wherein the second transistor comprises a second channel that is oriented in a direction orthogonal to the first direction; and
arranging, in an integrated circuit, the plurality of standard cells, wherein each of a plurality of metal gates, within at least one adjoining pair of standard cells of the plurality of standard cells, is an active gate.

9. The method as recited in claim 8, further comprising forming the plurality of standard cells such that standard cells of the at least one adjoining pair of standard cells have one or more active regions with a length equal to a distance between a source region and a drain region of a single transistor.

10. The method as recited in claim 9, further comprising forming the plurality of standard cells such that the standard cells of the at least one adjoining pair of standard cells comprise a source region or a drain region at an edge of one of the standard cells.

11. The method as recited in claim 10, further comprising forming the plurality of standard cells such that the standard cells of the at least one adjoining pair of standard cells share the source region or the drain region at the edge.

12. The method as recited in claim 9, further comprising forming the plurality of standard cells such that the plurality of standard cells comprises a given group of instantiated standard cells that form an L-shape that provides available on-die area for another non-instantiated standard cell.

13. The method as recited in claim 9, further comprising forming the plurality of standard cells such that the non-planar transistors comprise pairs of transistors with channels of opposite doping polarities with only one transistor of a corresponding pair of transistors being adjacent to a silicon substrate.

14. The method as recited in claim 13, wherein responsive to a potential being applied to an input node of the integrated circuit, the method further comprises conveying, by one or more of the standard cells, a current from the input node to an output node of the integrated circuit.

15. A processor comprising:
a memory configured to store instructions of one or more tasks and source data to be processed by the one or more tasks; and
computing core circuitry configured to execute the instructions of the one or more tasks using the source data; and
wherein the computing core circuitry includes an integrated circuit comprising:
a plurality of standard cells, one or more of the standard cells comprising non-planar transistors;
wherein each of a plurality of metal gates, within at least one adjoining pair of standard cells of the plurality of standard cells, is an active gate.

16. The processor as recited in claim 15, wherein standard cells of the at least one adjoining pair of standard cells have one or more active regions with a length equal to a distance between a source region and a drain region of a single transistor.

17. The processor as recited in claim 16, wherein the standard cells of the at least one adjoining pair of standard cells comprise a source region or a drain region at an edge of one of the standard cells.

18. The processor as recited in claim 17, wherein the standard cells of the at least one adjoining pair of standard cells share the source region or the drain region at the edge.

19. The processor as recited in claim 16, wherein the plurality of standard cells comprises a given group of instantiated standard cells that form an L-shape that provides available on-die area for another non-instantiated standard cell.

20. The processor as recited in claim 16, wherein the non-planar transistors comprise pairs of transistors with channels of opposite doping polarities with only one transistor of a corresponding pair of transistors being adjacent to a silicon substrate.
